(19) United States
(12) Patent Application Publication
(10) Pub. No.: US 2019/0006584 A1
(43) Pub. Date: Jan. 3, 2019

(54) METHOD FOR IMPROVING ENDURANCE PERFORMANCE OF 3D INTEGRATED RESISTIVE SWITCHING MEMORY

(71) Applicant: INSTITUTE OF MICROELECTRONICS, CHINESE ACADEMY OF SCIENCES, Beijing (CN)

(72) Inventors: Nianduan LU, Chaoyang District, Beijing (CN); Pengxiao SUN, Chaoyang District, Beijing (CN); Ling LI, Chaoyang District, Beijing (CN); Ming IIU, Chaoyang District, Beijing (CN); Qi LIU, Chaoyang District, Beijing (CN); Hangbing LV, Chaoyang District, Beijing (CN); Shibing LONG, Chaoyang District, Beijing (CN)

(73) Assignee: Institute of Microelectronics, Chinese Academy of Science, Beijing (CN)

(21) Appl. No.: 16/064,120

(22) PCT Filed: Aug. 12, 2016
(86) PCT No.: PCT/CN2016/094863

§ 371 Date: Jun. 20, 2018

(30) Foreign Application Priority Data
Dec. 24, 2015 (CN) 201510983165.X

(51) Int. Cl. H01L 45/00

(52) U.S. Cl. CPC H01L 45/126; H01L 45/14; H01L 45/16; H01L 45/128

(57) ABSTRACT

A method for improving endurance of 3D integrated resistive switching memory, comprising: Step 1: Calculating the temperature distribution in the integrated array by the 3D Fourier heat conduction equation; Step 2, selecting heat transfer mode; Step 3: selecting an appropriate array structure; Step 4: analyzing the influence of integration degree on temperature in the array; Step 5: evaluating the endurance performance in the array; and Step 6: changing the array parameters according to the evaluation result to improve the endurance performance. According to the method of the present invention, based on the thermal transmission mode in the 3D integrated resistive switching device, a suitable 3D integrated array is selected to analyze the influence of the integration degree on the device temperature so as to evaluate and improve the endurance of the 3D integrated resistive switching device.

### TECHNICAL FIELD

The invention belongs to the technical field of microelectronic devices and memories, and in particular relates to a method for improving the endurance performance of 3D integrated resistive switching memory (RRAM).

### BACKGROUND TECHNIQUE

When a device is operated under voltage, the temperature of the device itself will change due to the effect of Joule heat. Therefore, the thermal effect caused by Joule heat is a common phenomenon in semiconductor devices. Different materials in semiconductor devices have different coefficients of expansion after being heated, so the thermal stress inside the device will be unevenly distributed accordingly. With the increasing integration of three-dimensional (3D) integrated resistive switching memory (RRAM), the number of memory cells has increased dramatically, and this thermal effect caused by Joule heat will become more serious. Therefore, with the increasing of integration, the biggest challenge that 3D integrated RRAM has to face is how to solve the thermal effect problem of the device, wherein the impact of heat distribution on RRAM devices (such as energy consumption, thermal stability, etc.) has become particularly prominent accompanied by the decrease of the feature size of the device. In particular, as the density of memory cells continues to increase, the distance between adjacent cells decreases and thermal crosstalk between adjacent cells severely restricts the development and application of 3D integrated RRAM.

With regard to 3D integrated resistive switching memory, many domestic and overseas research groups have invested a lot of energy in research and achieved good results. However, due to the difficulty of experimental measurement of thermal effects in 3D integration of resistive switching memory, current thermal analysis methods are hard to perform. So, there have been few reports on the endurance characteristics of 3D resistive switching memory under the action of Joule heat effect. The related technical means still need to be further studied.

### SUMMARY OF THE INVENTION

From the above, the purpose of the present invention is to provide a method for improving the endurance performance of 3D integrated resistive switching memory in order to overcome the shortcomings of the study on thermal effects of current 3D integrated resistive switching memory devices.

To this end, the present invention provides a method for improving endurance performance of 3D RRAM array, including the steps of:
Step 1: calculating the temperature distribution in the integrated array by the 3D Fourier heat conduction equation;
Step 2, selecting heat transfer mode;
Step 3: selecting an appropriate array structure;
Step 4: analyzing the influence of integration degree in the array on temperature;
Step 5: evaluating the endurance performance in the array;
Step 6: changing the array parameters according to the evaluation result to improve the endurance performance.

Wherein the 3D Fourier heat conduction equation in step 1 is

$$∇ {k}_{th} ∇ T + σ \vert ∇ V {\vert}^{2} - c ρ \frac{\partial T}{\partial t} = 0 \qquad ( 1 )$$

wherein kₜₕ denotes heat conduction, T denotes temperature, c denotes heat capacity, ρ denotes mass density of the material, t denotes time, and σ denotes conductivity of the material; preferably the conductivity of the material will generally change with temperature and can be expressed as shown in formula (2),

$$σ = \frac{{σ}_{0}}{1 + α ( T - {T}_{0} )} , \qquad ( 2 )$$

in formula (2), α denotes the temperature coefficient of resistance, and σ₀ denotes the resistivity at room temperature T₀, further preferably the word line (WL) and bit line (BL) at the top and bottom of the array are assumed to have an ideal heat dissipation package structure, and the temperature at the top and bottom is maintained at room temperature T₀ during calculation as shown in formula (3):

T−T₀|_{BC}=0 (3).

Wherein the heat transfer mode is that
(i) heat is transferred between the devices in same layer via the isolating dielectric material, or
(ii) heat is transferred between the RRAM devices in different layers in vertical direction.

Wherein the array structure is a 3D array of device units, each of which consists of one RRAM and one diode.

Wherein in step 5, the thermal effect of the 3D integrated resistive switching device is analyzed by using the formula described in step 1 based on the physical parameters of conductive filaments, diodes, and WL/BL of the RRAM device, wherein the physical parameters are selected from any one of the following or any combinations thereof: radius, thickness, thermal conductivity, heat capacity, reference conductivity at room temperature, width, reset voltage, and room temperature.

Wherein the endurance performance is estimated by using the effect of transient temperature on the life of electrode based on the Arrhenius law of the memory device in step 5; preferably number of endurance n_{endurance} can be expressed as follows by combining with the RRAM's reset time tᵣₑₛₑₜ and the transient temperature in the electrode portion at t=50 ns

$${n}_{endurance} = \frac{{t}_{life time}}{{t}_{reset} - 50 ns} , \qquad ( 4 )$$

in the formula, t_{lifetime} represents the life of the electrode, based on the Arrhenius's law: t_{lifetime}∝e^{(qEa/kTp)}, wherein q represents the elementary charge, k is Boltzmann's constant, and Ea is the activation energy of the metal atom thermal diffusion in the surrounding isolation material.

Wherein step 6 includes isolating the electrode portion with a dielectric material of high metal migration activation energy.

According to the method of the present invention, considering the thermal transmission mode in the 3D integrated resistive switching memory, a suitable 3D integrated array is selected to analyze the influence of the integration degree on the device temperature so as to evaluate and improve the endurance performance of the 3D integrated resistive switching device.

### DESCRIPTION OF THE DRAWINGS

Hereinafter, the technical solution of the present invention will be described in detail with reference to the accompanying drawings, in which:

FIG. 1 shows a schematic diagram of possible heat conduction paths (white arrows) in the 3D integrated cross array provided by the present invention.

FIG. 2(a) is a schematic structural view of a 3D integrated resistive switching memory device employed in the present invention, and FIG. 2(b) is a single device unit including a resistive switching memory cell (RRAM), an electrode and a diode connected in series.

FIG. 3 is a schematic structural view of 3D integrated resistive switching memories in three different integration degree: (a) 3×3×1, (b) 3×3×2, and (c) 3×3×3.

FIGS. 4(a)-(c) are schematic diagrams of the selected array structures; FIGS. 4(d)-(f) are the temperature dynamic change plots of a programmed device, in which the array size is respectively (a) 3×3×1, (b) 3×3×2, and (c) 3×3×3; programmed RRAM is connected to light-colored diodes; unprogrammed RRAM is connected to dark-colored diodes; light-colored W/B lines are applied by voltage V, dark-colored W/B lines are grounded.

FIG. 5 shows the variation of the maximum temperature of the electrode portion with time in three different arrays of 3×3×1, 3×3×2, and 3×3×3, corresponding to FIGS. 4(a)-(c).

FIG. 6 shows the dependence of the system's endurance characteristics on Eₐ in three different arrays of 3×3×1, 3×3×2, and 3×3×3.

FIG. 7 is a schematic flow chart of a method according to the present invention.

### DETAILED DESCRIPTION

The characteristics and technical effects of the technical solution of the present invention will be described in detail below with reference to the accompanying drawings and exemplary embodiments. A method for effectively improving the endurance performance of a 3D RRAM array is disclosed. It should be noted that like reference numerals refer to like structures, and the terms “first”, “second”, “upper”, “lower” and the like used herein may be used to modify various device structures or manufacturing processes. Such modifications, unless specified, do not imply a spatial, order or hierarchical relationship between the structure of the modified device or the manufacturing process.

The method includes the following steps:

Step 1: Calculating the Temperature Distribution in the Integrated Array by the 3D Fourier Heat Conduction Equation

The temperature distribution in the RRAM 3D integrated array can be described using various heat conduction models and their corresponding equations, but based on the accuracy considerations, the 3D Fourier heat conduction equation shown in formula (1) is optimally described:

$$σ = \frac{{σ}_{0}}{1 + α ( T - {T}_{0} )} , \qquad ( 2 )$$

In equation (1), kₜₕ denotes heat conduction, T denotes temperature, c denotes heat capacity, ρ denotes mass density of the material, t denotes time, and σ denotes conductivity of the material. The conductivity of the material will generally change with temperature and can be expressed as formula (2),

$$∇ {k}_{th} ∇ T + σ \vert ∇ V {\vert}^{2} - c ρ \frac{\partial T}{\partial t} = 0 \qquad ( 1 )$$

In formula (2), α denotes the temperature coefficient of resistance, and σ₀ denotes the resistivity at room temperature T₀. The word line (WL) or bit line (BL) at the top and bottom of the array are assumed to have an ideal heat dissipation package structure, and the room temperature is maintained at T₀ during calculation as shown in formula (3):

T−T₀|_{BC}=0 (3)

In order to accurately calculate the temperature effect of the device in the present invention, a 3D resistance network model is used in the conductivity simulation, and the calculation theory is based on Ohm's law and Kirchhoff's equation. It is often difficult to accurately calculate the heat distribution of the entire device array, but certain characterization areas (specific device structures) in the array may be selected for the local array (e.g. the test structures fabricated in the dummy cells on a wafer). The relationship between the measured value (local area temperature or thermal imaging spectral line, etc.) and the theoretical calculation value corrects the subsequent process, for example, the experimental data feedback is used in the modification to improve accuracy and change the actual array structure of the future design, and the like.

Step 2: Considering the Heat Transfer Mode in 3D Integrated Resistive Switching Devices

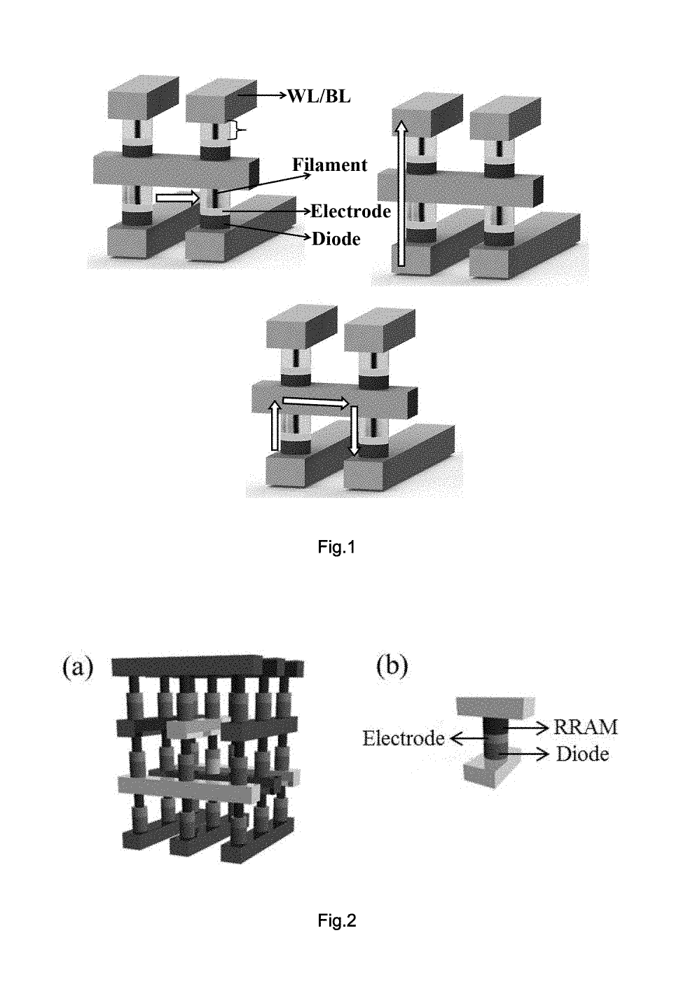

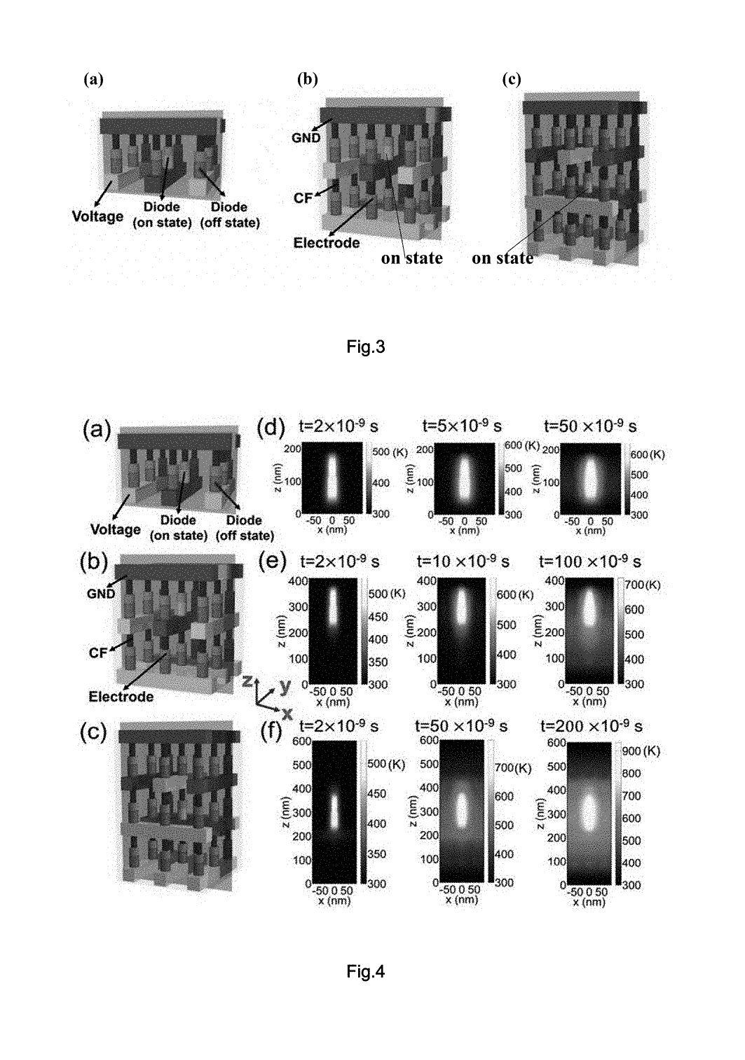

FIG. 1 shows several possible thermal conduction paths (shown by white arrows) in a 3D integrated RRAM crossbar array. A single RRAM device generates heat and then the heat can be transferred between the devices in the same layer via the isolating dielectric material, can also be transferred vertically between different layers of RRAM devices, or can be transferred between adjacent cells. In addition, the heat conduction of the W/B line in the RRAM device is also very significant due to its higher thermal conductivity. Specifically, by analyzing the device structure, especially based on the heat distribution corresponding to different heat transfer modes and their subsequent thermal crosstalk effects, a suitable heat transfer mode and its corresponding stack structure of RRAM and diodes are set (that is, selected in the next batch of RRAM array manufacturing).

Step 3: Selecting the Appropriate 3D Integrated Array

The corresponding heat distribution of the current device (RRAM array) is calculated (or simulated) according to the heat transfer model, and the appropriate array structure is selected for subsequent thermal crosstalk evaluation. And follow-up can be feedback to modify the array structure design in next batch of production based on the evaluation results,

FIG. 2 shows a schematic structural diagram of a device used in the present invention. It is a crossbar array structure of 1D1R (D represents a diode and R represents a resistive switching memory cell). Namely the device cell consists of a resistive random switching cell (RRAM), an electrode and a diode (Diode) connected in series, as shown in FIG. 2(b). In FIG. 2(b) the structures in same layer are A (RRAM-electrode-diode), and are also arranged between layer to layer according to this structure (namely: AAAA; other arrangements are A-B-A-B or A-B-B-A etc., wherein the structure of B is diode-electrode-RRAM).

Step 4: Analyzing the Influence of Programming Device Integration Degree in 3D Integrated Resistive Switching Device on Temperature.

Based on the heat conduction path shown in step 2, the heat distribution of the 3D integrated resistive switching device can be calculated by combining the formula in step 1. The larger the integration degree of the device, the faster the RRAM device will rise in temperature during the programming operation. In addition, since the electrode portion is directly connected to the conductive filaments, the larger the scale of array, the faster the temperature rises at the electrode portion. Temperature and device integration degree have a certain relationship. Although it is difficult to describe in a specific functional relationship (that is, to give a complete equation), it can be used to fit by a number of experimental tests and theoretical calculations at local structure.

Firstly, according to the device structure characteristic of step 3, a RRAM of a crossbar structure of 3×3×1, 3×3×2, and 3×3×3 is respectively established, the feature size of which is 100 nm to 30 nm. Then the thermal effects of 3D integrated resistive switching device is analyzed using the formula and method described in Step 1 and the basic physical parameters listed in Table 1. Among them, it is worthy of special attention that the device size has a significant influence on the temperature distribution, for example, a decrease in the device size leads to a significant change in the temperature distribution (for example, increase, quadraticly or cubicly increase, exponential increase, etc.).

TABLE 1
Physical parameters used in the simulation

| parameter | value | | parameter | value | | parameter | value | |
|---|---|---|---|---|---|---|---|---|
| r_{cf} | 8 | nm | r_{diode} | 40 | nm | hₗᵢₙₑ | 30 | nm |
| h_{cf} | 80 | nm | h_{diode} | 50 | nm | kₜₕ_{_{—}}_{diode} | 22 | W/(m K) |
| kₜₕ_{_{—}}_{cf} | 22 | W/(m K) | kₜₕ_{_{—}}_{diode} | 11.7&2 | W/(m K) | cₗᵢₙₑ | 445 | J/(kg K) |
| c_{cf} | 445 | J/(kg K) | c_{diode} | 710 | J/(kg K) | σ₀_{_{—}}ₗᵢₙₑ | 1.23 × 10⁵ | S/m |
| σ_{0cf} | 1.23 × 10⁵ | S/m | σ₀_{_{—}}_{diode} | 3.07 × 10³ &5 × 10⁻² S/m | | ρₗᵢₙₑ | 8.9 × 10³ | Kg m⁻³ |
| α_{cf} | 0.0014 | | ρ_{diode} | 4.17 × 10³ | Kg m⁻³ | V_{b)} | 1.2 | V |
| ρ_{cf} | 8.9 × 10³ | Kg m⁻³ | wₗᵢₙₑ | 100 | nm | T₀ | 300 | K |

In the table, r represents the radius, h represents the thickness, kₜₕ represents the thermal conductivity, c represents the heat capacity, σ₀ represents the reference conductivity at room temperature, w represents the width, subscript cf, diode and line respectively represents conductive filaments (CF), diodes (Diode) and Word Line/Bit Line (WL/BL) cells. V represents the reset voltage and T₀ is room temperature. In Table 1, kₜₕ_{_{—}}_{diode} and σ₀_{_{—}}_{diode} list two values respectively corresponding to the parameter value in the diode forward conduction state and reverse shutdown state.

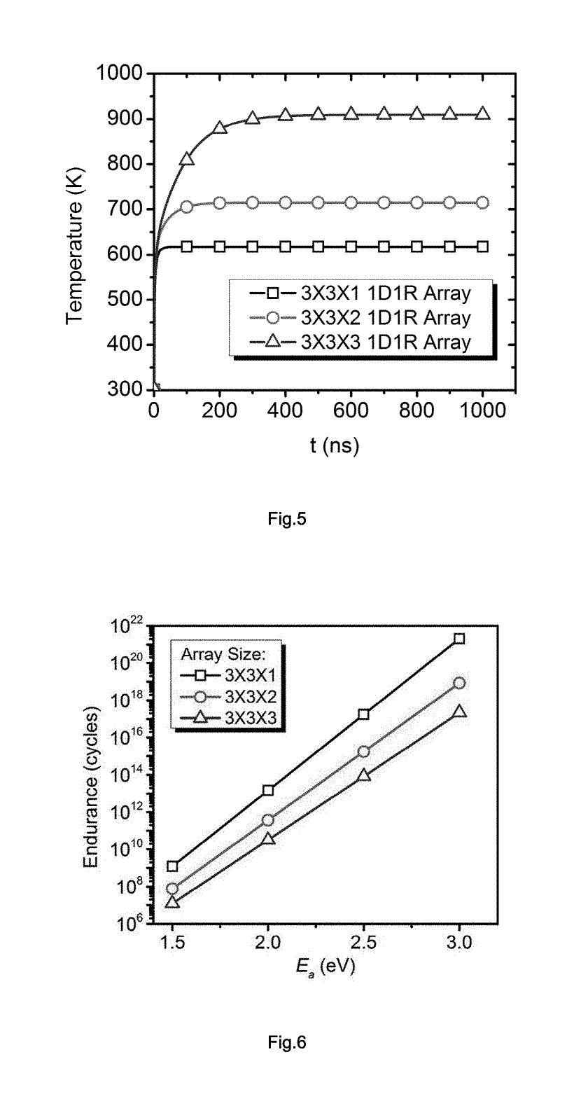

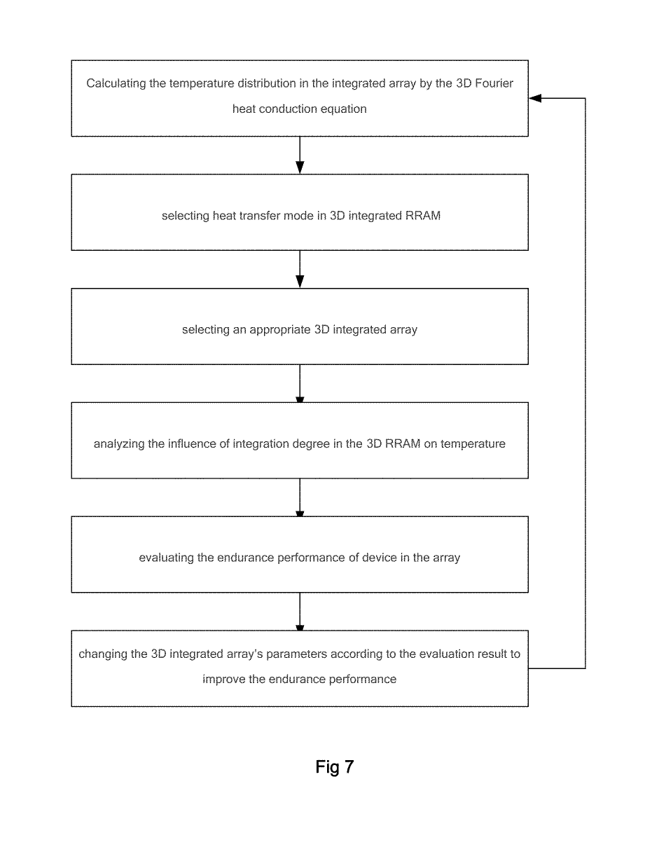

The results of the thermal distribution calculation of the 3D integrated resistive switching memory with different integration degree are shown in FIG. 4 and FIG. 5. FIG. 4 shows the temperature distribution variation of the system with the programming device in the middle of the integrated array. FIG. 5 shows the maximum temperature variation over time of a programmed RRAM device. It can be seen from FIG. 4 and FIG. 5 that the temperature rises sharply during the programming operation of the RRAM device. Since the electrode portion is directly connected to the conductive filaments, the temperature of the electrode portion rises sharply, and the larger array has a higher temperature.

Step 5: Evaluating Endurance Characteristics in 3D Integrated Resistive Switching Devices

With the shrink of the size of the 3D integrated resistive switching device, the performance degradation process of the electrode portion is similar to that of the low resistive state retention characteristic of the conductive filament of the unipolar RRAM device at a small size. The present invention uses a simple method to evaluate the endurance performance n_{endurance} of the array system. n_{endurance} can be expressed as follows combining with the RRAM's reset time tᵣₑₛₑₜ and the transient temperature in the electrode portion at t=50 ns:

$${n}_{endurance} = \frac{{t}_{life time}}{{t}_{reset} - 50 ns} , \qquad ( 4 )$$

In the formula, t_{lifetime} represents the life of the electrode, based on the Arrhenius's law: t_{lifetime}∝e^{(qEa/kTp)}, wherein q represents the elementary charge, k is Boltzmann's constant, and Ea is the activation energy of the metal atom thermal diffusion in the surrounding isolation material. The larger the Ea, the harder the metal atoms migration and the longer the life characteristics of electrode portion. In addition, in the present invention, it is assumed that the electrode portion has a lifetime of 10 years when Ea=1.5 eV, and T=400 K.

Step 6: Method for improving the endurance of 3D integrated resistive switching devices

From the analysis on the thermal effect of the 3D integrated resistive random access memory and the lifetime of the electrode material in the above steps 1, 2, 3, 4, and 5, the present invention provides a method that can improve the endurance characteristics of 3D integrated resistive devices by using a larger activation energy of the metal atom thermal diffusion in the surrounding isolation material.

For example, according to the method for evaluating the endurance characteristic in the 3D integrated resistive switching device described in step 5, the endurance performances of the three different integrated array systems and their dependence on Ea are evaluated. The results show that the endurance performance of the array is significantly improved as Ea increases. Taking the 3×3×3 array as an example, when Ea is increased from 1.5 eV to 3 eV, the endurance characteristic of the array can be increased from 10⁷ to 10¹⁷, promoting 10¹⁰ times, as shown in FIG. 6. Therefore, it can significantly increase the number of endurances of the RRAM array to use a dielectric material with high metal migration activation energy for the isolation in the electrode portion. Since the high metal migration activation energy medium material (according to Ea size, such as Al>Ni>Ag, Cu, Pd>Pt, Au, all of the electrode materials in the resistance switching memory are metal, and the corresponding dielectric materials are the oxide of these materials) will not bring about parasitic effects, the selected electrode is generally Pt, Ag, Cu, Au, etc., so that the electrode material will not affect Ea.

According to the method of the present invention, based on the thermal transmission mode in the 3D integrated resistive switching device, a suitable 3D integrated array is selected to analyze the influence of the integration degree on the device temperature so as to evaluate and improve the endurance of the 3D integrated resistive switching device.

Although the invention has been described with reference to one or more exemplary embodiments, those skilled in the art will appreciate that various suitable changes and equivalent arrangements of the device structure or method flow may be made without departing from the scope of the invention. In addition, from the teachings disclosed, many modifications may be made to suit a particular situation or material without departing from the scope of the invention. Therefore, the present invention is not intended to be limited to the specific embodiments disclosed as the best mode for carrying out the present invention, but the disclosed device structure and the manufacturing method thereof will include all the embodiments falling within the scope of the present invention.

1. A method for improving endurance of 3D RRAM array, the method comprising:
calculating the temperature distribution in the integrated array by the 3D Fourier heat conduction equation;
selecting heat transfer mode;
selecting an appropriate array structure;
analyzing the influence of integration degree in the array on temperature;
evaluating the endurance performance of devices in the array; and
changing the array parameters according to the evaluation result to improve the endurance performance.

2. The method of claim 1, wherein the 3D Fourier heat conduction equation is
$$∇ {k}_{th} ∇ T + σ \vert ∇ V {\vert}^{2} - c ρ \frac{\partial T}{\partial t} = 0 \qquad ( 1 )$$
wherein kₜₕ denotes heat conduction, T denotes temperature, c denotes heat capacity, ρ denotes mass density of the material, t denotes time, and σ denotes conductivity of the material; preferably the conductivity of the material will generally change with temperature and can be expressed as formula (2),
$$σ = \frac{{σ}_{0}}{1 + α ( T - {T}_{0} )} \qquad ( 2 )$$
in formula (2), α denotes the temperature coefficient of resistance, and σ₀ denotes the resistivity at room temperature T₀, further preferably the word line (WL) and bit line (BL) at the top and bottom of the array are assumed to have an ideal heat dissipation package structure, and the temperature at the top and bottom is maintained at room temperature T₀ during calculation as shown in formula (3):
T−T₀|_{BC}=0 (3).

3. The method of claim 1, wherein in the heat transfer mode:
heat is transferred between the devices in same layer via the isolating dielectric material, or
heat is transferred in vertical direction between the RRAM devices in different layers.

4. The method of claim 1, wherein the array structure is a 3D array of device units, each of which comprises one RRAM and one diode.

5. The method of claim 2, wherein the thermal effect of the 3D integrated resistive switching device is analyzed by using the formula described in step 1 based on the physical parameters of conductive filaments, diodes, and WL/BL of the RRAM device, wherein the physical parameters are selected from any one of the following or any combinations thereof: radius, thickness, thermal conductivity, heat capacity, reference conductivity at room temperature, width, reset voltage, and room temperature.

6. The method of claim 1, wherein the endurance is measured using the effect of transient temperature on the life of electrode based on the Arrhenius law of the memory device; a number of endurance n_{endurance} can be expressed by combining the RRAM's reset time tᵣₑₛₑₜ and the transient temperature in the electrode portion at t=50 ns as defined by equation (4)
$${n}_{endurance} = \frac{{t}_{life time}}{{t}_{reset} - 50 ns} \qquad ( 4 )$$
wherein t_{lifetime} represents the life of the electrode, based on the Arrhenius's law: t_{lifetime}∝e^{(qEa/kTp)}, wherein q represents the elementary charge, k is Boltzmann's constant, and Ea is the activation energy of the metal atom thermal diffusion in the surrounding isolation material.

7. The method of claim 1, wherein changing the array parameters according to the evaluation result to improve the endurance performance isolating the electrode portion with a dielectric material of high metal migration activation energy.
